(19) United States
(12) Patent Application Publication
(10) Pub. No.: US 2006/0278373 A1
(43) Pub. Date: Dec. 14, 2006

(54) Microchannel cooling device with magnetocaloric pumping

(75) Inventor: Li-Chieh Hsu, Danshui Town (TW)

Correspondence Address: BRUCE H. TROXELL, SUITE 1404, 5250 LEESBURG PIKE, FALLS CHURCH, VA, 22041, US

(73) Assignee: Industrial Technology Research Institute

(21) Appl. No.: 11/184,965

(22) Filed: Jul. 20, 2005

(30) Foreign Application Priority Data
Jun. 9, 2005 (TW) 94118988

(51) Int. Cl. H05K 7/20; F28D 15/00; H02K 44/00

(52) U.S. Cl. 165/104.33; 361/699; 417/50

(57) ABSTRACT

The invention discloses a microchannel cooling device, adapted for dissipating heat generated from an electronic device, which comprises: a heat sink, being arranged on the electronic device and having an inlet, an outlet and a plurality of microchannels embedded thereon for receiving a ferrofluid to flow therein; a condenser, having an outlet connected to the inlet of the heat sink and an inlet connected to the outlet of the heat sink; and a magnetocaloric pump, for providing a magnetic field to the ferrofluid flowing in the heat sink; wherein the magnetocaloric effect (MCE) caused by the working of the magnetic field on the ferrofluid flowing in the heat sink is used for driving the ferrofluid to flow through the plural microchannels of the heat sink while absorbing heat therefrom, and thereafter, the heated ferrofluid flow into the condenser for discharging heat and then the cool-down ferrofluid is guided back to the heat sink to complete a circulation. The invention make use of the high heat transfer performance of the plural microchannels, the nature circulation caused by the loop thermosyphone and the driving of the magnetocaloric pump so as to constitute a cooling device with no mechanically moving elements.

### FIELD OF THE INVENTION

The present invention relates to a microchannel cooling device, and more particularly, to a microchannel cooling device utilizing a magnetocaloric pump for driving a ferrofluid flowing therein to form a heat-dissipating circulation.

### BACKGROUND OF THE INVENTION

In 1965, Gordon Moore, Director of Fairchild Semiconductor's Research and Development Laboratories, wrote an article on the future development of semiconductor industry for the 35th anniversary issue of Electronics magazine. In the article, Moore noted that the complexity of minimum cost semiconductor components had doubled per year since the first prototype microchip was produced in 1959. This exponential increase in the number of components on a chip became later known as Moore's Law. In the recent decade, as predicted by the Moore's Law, the manufacturing process of semiconductor had progressed from the 0.7 mm process with 100K transistors on an integrated circuit of fixed size at 1989 to the 0.13 mm process with 5M transistors on an integrated circuit of fixed size at 2000, and is estimated to reach 0.1 mm process with 10M transistors on an integrated circuit of fixed size at the early 21^{st} century, which is going to be the age of nanometer.

As the number of transistors on a single chip has grown 300 million-fold since Intel introduced its first microprocessor 35 years ago that represents a performance increase of about 80 percent per year, the cramping of transistors on a chip of limited area has brought the heat dissipation issue to become a challenge for continuing the aforesaid progress as predicted by Moore's Law.

No matter it is a personal computer or a notebook computer, both are troubled by the same heat dissipation problem. Even with cooling fans installed in the both, not to mention that the heat dissipating efficiency of the cooling fan is questionable, the increasing of power consumption and overall weight will be the additional problems requiring to be addressed. According to Moore's Law, the number of transistors on a chip roughly doubles every two years, resulting in more features, increased performance and decreased cost per transistor. As transistors get smaller, heat dissipation issues develop.

As the performance of CPU is increasing while generating more heat to be dissipated, the conventional heat dissipation technology for electronic devices, i.e. fan thermal module, is no longer capable of meeting the requirement of the future high performance CPUs. The rotation speed of a current cooling fan is about 7000 rpm while generating noise of 60 dB, and the heat flux of a typical thermal tube, restricted by capillary attraction and speed of heat transfer, is only 7˜8 W/cm², which has already reached the bottleneck of their development. Therefore, in order to meet the heat dissipation requirement of the future high performance CPUs, that is, heat load: 150 W and heat flux: 23 W/cm² for the CPUs of next three to five years, a new generation of heat dissipation technology is required. There is another heat dissipation technology for electronic devices, i.e. liquid cooling system, whose heat flux can be more than ten times that of the aforesaid air cooling system. However, a pump is required in the liquid cooling system for driving coolant to circulate therein, which can be as bulky as the size of 100×50×86 mm for example and is very noisy while operating. Moreover, the heat transfer efficiency of a liquid cooling system might be limited, since heat transfer can only occur at the boundary layer close to the wall of the tube containing the coolant of the liquid cooling system whereas the majority of the coolant is flowing at the proximity of the center of the tube. It is noted that by dividing a major conduit of a liquid cooling system into a plurality of parallel-arranged microchannels, larger portion of coolant is enabled to flow within boundary layer in each microchannel such that the heat transfer coefficient of the liquid cooling system can be increased.

There are several prior-art techniques have been disclosed for cooling down the temperature of the microprocessor while keeping the same in a specific working temperature. For instance, the U.S. Pat. No. 6,704,200, entitled “LOOP THERMOSYPHON USING MICROCHANNEL ETCHED SEMICONDUCTOR DIE AS EVAPORATOR”, discloses a loop thermosyphon system, comprising: a semiconductor die having a plurality of microchannels; and a condenser in fluid communication with the microchannels; and wicking structure to wick a fluid between the condenser to the semiconductor die; wherein the fluid can be selected from the group consisting of water, alcohol and Fluorienert. Nevertheless, although the referring loop thermosyphon system is capable of cooling down the temperature of a microprocessor, the dimension of the microchannel used in the invention is still too large such that its heat transfer coefficient is not satisfactory.

Moreover, in the U.S. Pat. No. 5,763,951, entitled “NON-MECHANICAL MAGNETIC PUMP FOR LIQUID COOLING”, a liquid cooling system contained completely on a circuit board assembly is disclosed. The liquid cooling system uses microchannels etched within the circuit board, those microchannels being filled with electrically conductive fluid that is pumped by a non-mechanical, magnetic pump. Although the aforesaid liquid cooling system is efficient in heat dissipation, it is adversely affected by its power consumption since it is required to provide electrical current to the magnetic pump for enabling the same to operate.

Therefore, there exists a need for a microchannel cooling device with loop thermosyphones circulation and magnetocaloric pumping.

### SUMMARY OF THE INVENTION

In view of the disadvantages of prior art, the primary object of the present invention is to provide a microchannel cooling device, which uses a magnetocaloric pump for driving a ferrofluid to flow through a plurality of microchannels so as to constitute a nature circulation without using any mechanically moving elements.

It is another object of the invention to provide a microchannel cooling device, featuring by using a magnetocaloric pump for driving a ferrofluid to flow through a plurality of microchannels while overcoming the friction and pressure loss exerting on the ferrofluid by each microchannel, whereas the magnetocaloric pump exhaust no additional power.

It is a further object of the invention to provide a microchannel cooling device, which can implement the nature circulation generated by loop thermosyphones to help increasing the flow speed of the ferrofluid flowing therein while consuming no additional power.

It is yet another object of the invention to provide a microchannel cooling device, which makes use of a phase-change heat dissipation technique performed in a plurality of microchannels so as to be good for electronic devices which power supply is limited such as laptop computers, whereas it can dissipate heat by nature circulations formed without power consumption.

To achieve the above objects, the present invention provides a microchannel cooling device, adapted for dissipating heat generated from an electronic device, which comprises: a heat sink, being arranged on the electronic device and having an inlet, an outlet and a plurality of microchannels embedded thereon enabling a ferrofluid to flow therein; a condenser, having an outlet connected to the inlet of the heat sink and an inlet connected to the outlet of the heat sink; and a magnetocaloric pump, for providing a magnetic field to the ferrofluid flowing in the heat sink, wherein the magnetocaloric effect (MCE) caused by the working of the magnetic field on the ferrofluid flowing in the heat sink is used for driving the ferrofluid to flow through the plural microchannels of the heat sink while absorbing heat therefrom, and thereafter, the heated ferrofluid flow into the condenser for discharging heat and then the cool-down ferrofluid is guided back to the heat sink to complete a self-circulation.

In a preferred aspect, the depth of each microchannel is 200 μm while the width of the same is ranged between 80 μm and 100 μm.

In a preferred aspect, the magnetocaloric pump further comprises: a first permanent magnet, being disposed at the inlet of the heat sink; and a second permanent magnet, being disposed at the outlet of the heat sink; wherein the direction of the magnetic field is in the direction pointed from the inlet of the heat sink to the outlet of the heat sink.

In a preferred aspect, the magnetocaloric pump further comprises a concave for accommodating the heat sink while the magnetic polarity of the portion of the concave next to the inlet of the heat sink is North and the magnetic polarity of the portion of the concave next to the outlet of the heat sink is South.

In a preferred aspect, the microchannel cooling device of the invention is a two-phase microchannel cooling device, further comprising: a two-phase conduit for connecting the outlet of the heat sink to the inlet of the condenser; and a conduit with pure liquid flowing therein for connecting the outlet of the condenser to the inlet of the heat sink.

In a preferred aspect, the heat sink further comprises a microchannel system formed by superimposing a cover on a substrate having a plurality of micro-grooves arranged thereon.

Other aspects and advantages of the present invention will become apparent from the following detailed description, taken in conjunction with the accompanying drawings, illustrating by way of example the principles of the present invention.

### BRIEF DESCRIPTION OF THE DRAWINGS

FIG. 1A is a schematic diagram showing a first preferred embodiment of the invention.

FIG. 1B is an A-A′ sectional view of FIG. 1 showing a cross-section of the heat sink according to the first preferred embodiment of the invention.

FIG. 1C is a schematic diagram showing the microchannel system according to the first preferred embodiment of the invention.

FIG. 2 is a schematic diagram depicting a two-phase circulation of the second preferred embodiment of the invention.

FIG. 3 is a schematic diagram showing a third preferred embodiment of the invention.

FIG. 4 is a profile depicting the relation of temperature change and the variation of magnetization of a magnetic material.

FIG. 5 is a schematic diagram depicting a two-phase circulation of the third preferred embodiment of the invention.

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

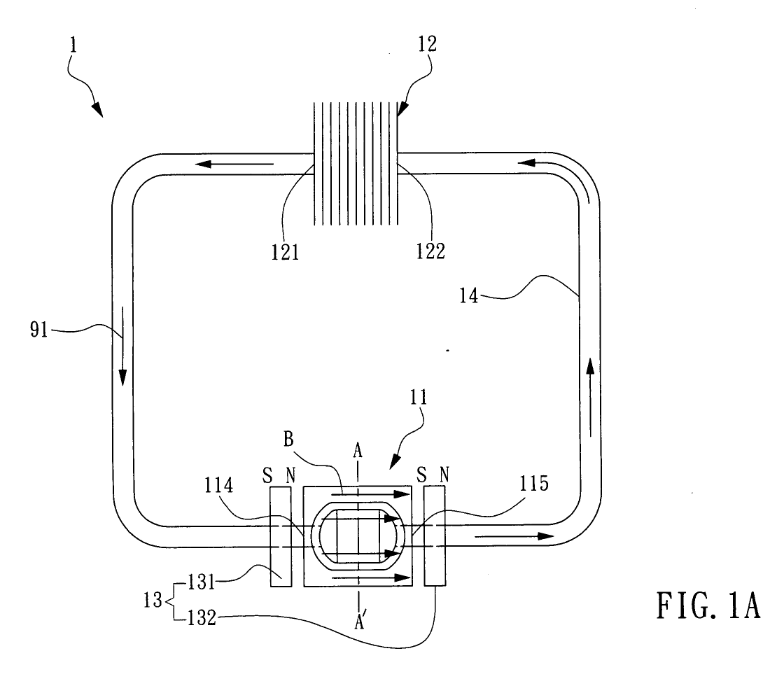

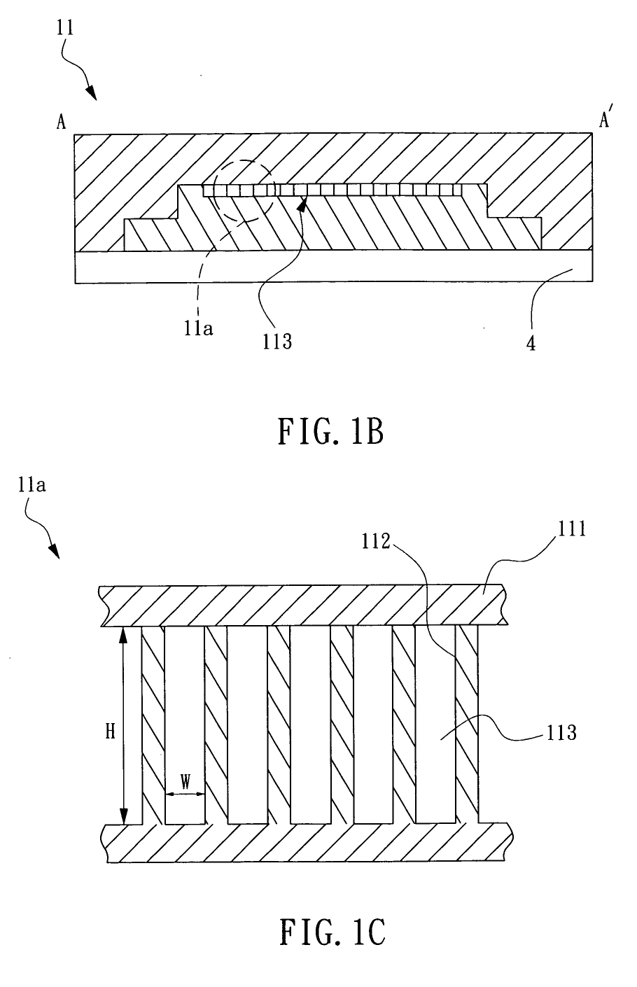

As seen in FIG. 1, a microchannel cooling device 1 of the invention comprises a heat sink 11 having an inlet 114 and an outlet 115, a condenser 12, a magnetocaloric pump 13 and a circulating conduit 14, wherein a loop is formed by connecting the inlet 114 and the outlet 115 respectively to the two ends of the circulating conduit 14. Please refer to FIG. 1B and FIG. 1C, which are respectively an A-A′ sectional view of FIG. 1 showing a cross-section of the heat sink and a schematic diagram showing the microchannel system according to the first preferred embodiment of the invention. The heat sink 11, having a plurality of microchannels 113 embedded thereon for receiving a ferrofluid to flow therein, is disposed on an electronic device 4 (e.g. a CPU) for absorbing heat generated from the same. In the preferred embodiment of the invention, the microchannel system of the plural microchannels 113 are formed by superimposing a cover 111 on a substrate having a plurality of micro-grooves 112 arranged thereon. In addition, the width W of each microchannel 113 is ranged between 80 μm and 100 μm while the depth H of each microchannel 113 is 200 μm such that the resistance of the ferrofluid flowing through the microchannel 113 can be controlled to an acceptable range.

Moreover, the outlet 121 of the condenser 12 is connected to the inlet 114 of the heat sink 11 by way of a portion of the circulating conduit 14 while the inlet 122 of the condenser 12 is connected to the outlet 115 of the heat sink 11 by way of another portion of the circulating conduit 14; and the magnetocaloric pump 13 further comprises: a first permanent magnet 131, being disposed at the inlet 114 of the heat sink 11; and a second permanent magnet 132, being disposed at the outlet 115 of the heat sink 11; wherein the direction of the magnetic field B is in the direction pointed from the inlet 114 to the outlet 115 of the heat sink 11.

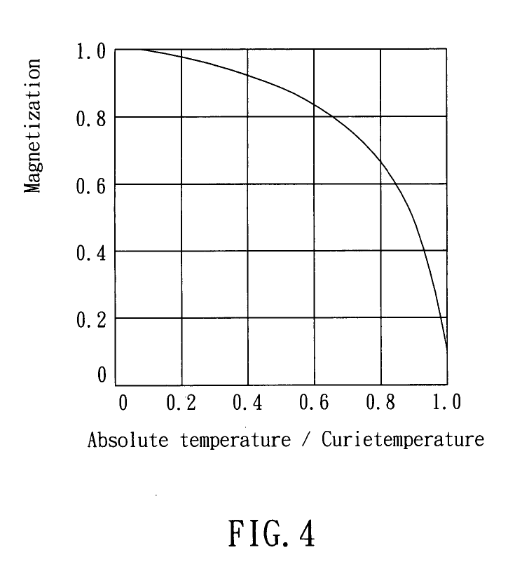

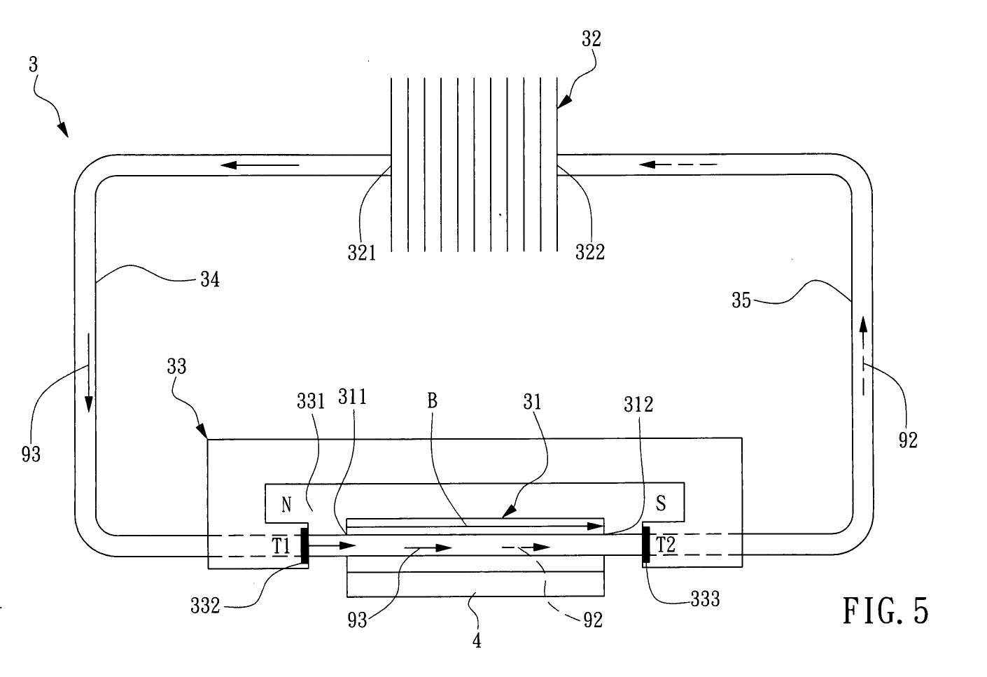

Please refer to FIG. 4, which is a profile depicting the relation of temperature change and the variation of magnetization of a magnetic material. It is noted that a magnetocaloric pump provides a simple means of pumping fluid using only external thermal and magnetic fields. The principle, which can be traced back to the early work of Rosensweig, is straightforward. Magnetic materials tend to lose their magnetization as the temperature approaches the material's Curie temperature. Exposing a column of magnetic fluid to a uniform magnetic field coincident with a temperature gradient produces a pressure gradient in the magnetic fluid. As the fluid heats up, it loses its attraction to the magnetic field and is displaced by cooler fluid. The impact of such a phenomenon is obvious: fluid propulsion with no moving mechanical parts. The formula of the pressure gradient is as following:
ΔP=μ₀H[M(T₁)−M(T₂)] (1)
wherein ΔP represents the pressure gradient;
   μ₀ represents permeability constant;
   H represents the intensity of the external magnetic field;
   M(T₁) represents the magnetization at the initial of the external magnetic field;
   M(T₂) represents the magnetization at the ending of the external magnetic field;
   T₁ represents the temperature of the ferrofluid at the initial of the external magnetic field;
   T₂ represents the temperature of the ferrofluid at the ending of the external magnetic field;
      Therefore, the pressure gradient is larger as the temperature difference between T₁ and T₂ is larger or the external magnetic field is larger, and thus fluid propulsion is larger.

As seen in FIG. 1A and FIG. 1B, the ferrofluid used in this preferred embodiment is properly chosen enabling the same to have no phase change during the circulation, that is, the ferrofluid is the mixture of oil, water and ferromagnetic material such that it remain in it liquid during the circulation. In this preferred embodiment, while the ferrofluid 91 is absorbing heat from the electronic device 4 at the heat sink 11, the temperature at the inlet 114 of the heat sink 11 is not the same as that at the outlet 115 such that the extend of magnetization of the ferrofluid 91 at these two locations are different as seen in FIG. 4. As the ferrofluid of different magnetization is subjecting to the magnetic field B, a pressure gradient following the formula (1) is formed between the inlet 114 and the outlet 115 of the heat sink 11 which can be used as the major propulsion forcing the ferrofluid 91 to flow from the heat sink 11 to the condenser 12 for discharging heat while overcoming the resistance of the ferrofluid 91 flowing through the microchannel 113. Therefore, the no-phase-change circulation of the ferrofluid 91 can be complete by the magnetocaloric effect without the help of any mechanically moving elements while the flowing of the ferrofluid 91 in the microchannels is enhanced.

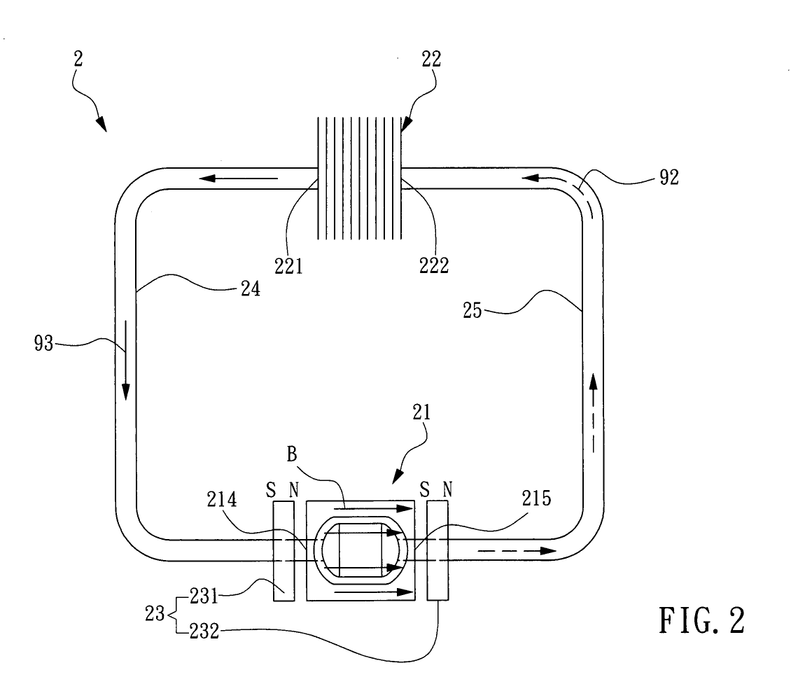

Please refer to FIG. 2, which is a schematic diagram showing a second preferred embodiment of the invention. The microchannel cooling device 2 of this preferred embodiment is substantially a two-phase microchannel cooling device with loop thermosyphones circulation and magnetocaloric pumping, which comprises a heat sink 21, a condenser 22 and a magnetocaloric pump 23. The detail structure of the heat sink 21, the condenser 22 and the magnetocaloric pump 23 are the same as that of the first embodiment of the invention and thus will not be described further hereinafter. The microchannel cooling device 2 further comprises: a two-phase conduit 25 for connecting the outlet 215 of the heat sink 21 to the inlet 222 of the condenser 22; and a conduit 24 with pure liquid flowing therein for connecting the outlet 221 of the condenser 22 to the inlet 214 of the heat sink 21. It is noted that the mixture of vapor-phase and liquid-phase ferrofluid 92 is flowing in the two-phase conduit 25 while only the liquid-state ferrofluid 93 is flowing in the conduit 24. In this preferred embodiment, the ferrofluid is consisted of a fluoride liquid and a plurality of magnetic particles, wherein the fluoride liquid can be substantially the FC-72, and the magnetic particle can the mixture of nano-scale iron, manganese, cobalt, zinc, nickel, chromium and the like, and more particularly, the nano-scale iron particle is a particle selected from the group consisting of Fe₂O₃, Fe₃O₄ and the mixtures thereof.

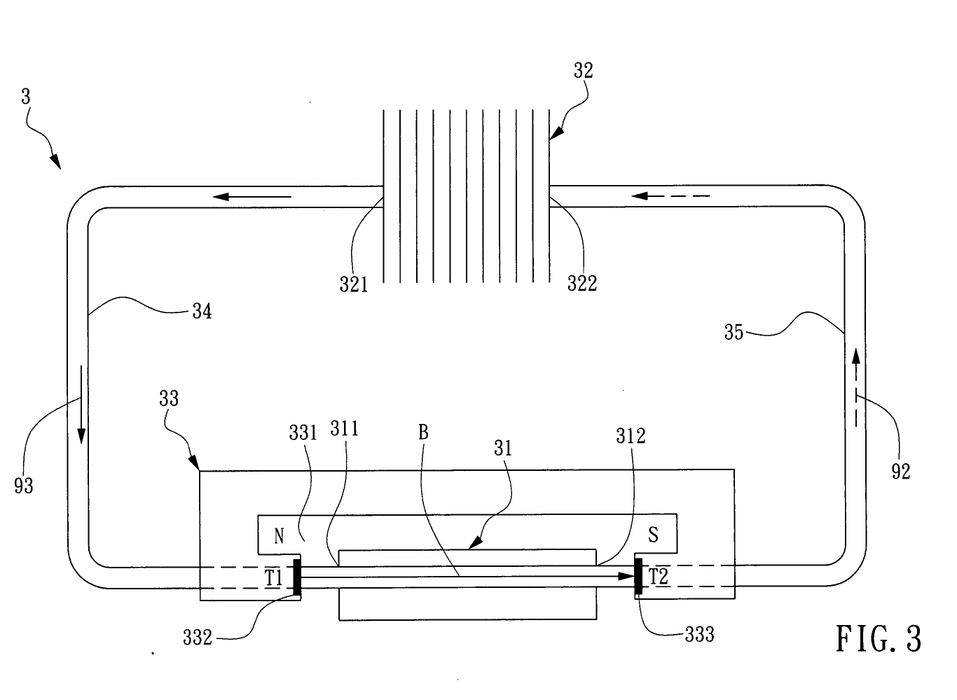

Please refer to FIG. 3, which is a schematic diagram showing a third preferred embodiment of the invention. In FIG. 3, the microchannel cooling device 3 comprises a heat sink 31, a condenser 32 and a magnetocaloric pump 33. The detail structure of the heat sink 31, the condenser 32 and the magnetocaloric pump 33 are the same as that of the first embodiment of the invention and thus will not be described further hereinafter. Moreover, the outlet 321 of the condenser 32 is connected to the inlet 311 of the heat sink 31 while the inlet 322 of the condenser 32 is connected to the outlet 312 of the heat sink 31; and the magnetocaloric pump 33, providing a magnetic field B to the ferrofluid flowing inside the heat sink 31, further comprises a concave 331 for accommodating the heat sink 31 while the magnetic polarity of the portion of the concave 331 next to the inlet 311 of the heat sink 31 is North 332 and the magnetic polarity of the portion of the concave 331 next to the outlet 312 of the heat sink 31 is South 333. The microchannel cooling device 3 further comprises: a two-phase conduit 35 for connecting the outlet 312 of the heat sink 31 to the inlet 322 of the condenser 32; and a conduit 34 with pure liquid flowing therein for connecting the outlet 321 of the condenser 32 to the inlet 311 of the heat sink 31. It is noted that the mixture of vapor-state and liquid-state ferrofluid 92 is flowing in the two-phase conduit 35 while only the liquid-state ferrofluid 93 is flowing in the conduit 34. In this preferred embodiment, the ferrofluid is consisted of a fluoride liquid and a plurality of magnetic particles, wherein the fluoride liquid can be substantially the FC-72, and the magnetic particle can the mixture of nano-scale iron, manganese, cobalt, zinc, nickel, chromium and the like, and more particularly, the nano-scale iron particle is a particle selected from the group consisting of Fe₂O₃, Fe₃O₄ and the mixtures thereof.

The second and the third embodiment of the invention is designed for the purpose of improving the flowing efficiency of ferrofluid. Thus, by selecting a proper ferrofluid, the heated ferrofluid is vaporized to generate the thermosyphone effect so that the vapor-state and the liquid-state ferrofluid co-exist in the circulation and thus the flow speed of the ferrofluid is increased. In these embodiments, the major circulation is relied on loop thermosyphon, the magnetocaloric pump is for overcoming the friction and pressure loss exerting on the ferrofluid by each microchannel.

The operation principle of the second and the third embodiment of the invention is illustrated in FIG. 2 and FIG. 5, which are schematic diagrams depicting a two-phase circulation of the third preferred embodiment of the invention. The heat sink 31, having a plurality of microchannels embedded thereon for receiving a ferrofluid 93 to flow therein, is disposed on an electronic device 4 (e.g. a CPU) for absorbing heat generated from the same. When the liquid-state ferrofluid 93 flow through the heat sink 31, the heat generated from the electronic device 4 is transferred to the heat sink 31 efficiently by the action of heat transfer. That is, since the dimensions of each microchannel of the heat sink 31 is specifically designed for enabling the majority of the liquid-state ferrofluid 93 to flow within the boundary layer of each microchannel and as the liquid-state ferrofluid 93 is being fed into the plural microchannels of the heat sink 31, the majority of the liquid-state ferrofluid 93 flowing in each microchannel can perform heat transfer with the wall of each microchannel and thus absorbing heat transferred from the electronic device 4 to the heat sink 31.

Thereafter, a portion of the ferrofluid 93 is vaporized during the ferrofluid 93 is traveling in each microchannel such that a mixed ferrofluid 92 containing both the vapor-state and liquid-state ferrofluid is formed accordingly. However, since the dimensions of each microchannel are specifically reduced, the friction exerting on the ferrofluid by the wall of each microchannel will cause the pressure loss to increase. It is noted that the temperature of the ferrofluid at the inlet 311 of the heat sink 31 is not the same as that at the outlet 312 (in some case, the temperature difference can be as large as 50° C. since the ferrofluid flowing in the microchannel is absorbing heat while traveling therein), and thus the magnetization of the magnetic particles of the ferrofluid flowing in the microchannel are not the same. Therefore, as the ferrofluid flowing between the inlet 311 and the outlet 312 is subjecting to the magnetic field B, a pressure gradient following the formula (1) is formed that it can be used to overcome the aforesaid friction and driving the ferrofluid to flow through the plural microchannels of the heat sink 31 while absorbing heat therefrom. As the mixed ferrofluid 92 is fed into the condenser 23 via the two-phase conduit 35, the heat dissipating capability of the condenser 23 will liquefy the vaporized ferrofluid into liquid-state ferrofluid while discharging the latent heat contained in the vapor-state ferrofluid, and thus the ferrofluid in liquid state can be guided to flow back to the heat sink 32 by the action of gravity via the conduit 34.

The means of cooling used in all the preferred embodiment of the invention is featuring of zero power consumption. As described in the second and the third embodiment of the invention, the heat sink is used for absorbing thermal energy and thus enabling the ferrofluid flowing in the microchannels thereof to vaporize and generate density difference for driving the ferrofluid to flow into the condenser for discharging heat, and thereafter, the condenser is capable of condensing the vaporized fluid and enable the same to mix with the unvaporized fluid so that the condensed fluid along with the unvaporized fluid can flow back to the heat sink by the action of gravity and thus complete a natural circulation. In addition, the magnetocaloric pump is used to increase the flow speed of the ferrofluid flowing in each microchannel. Thus, a microchannel cooling device of the invention can implement the nature circulation generated by loop thermosyphones and a magnetocaloric pump to help increasing the flow speed of the ferrofluid while consuming no additional power but only the heat generated from an electronic device, and eventually accomplish the objective of removing heat generated from the electronic device.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A microchannel cooling device, adapted for dissipating heat generated from an electronic device, comprising:
a heat sink, being arranged on the electronic device and having an inlet, an outlet and a plurality of microchannels embedded thereon for receiving a ferrofluid to flow therein;
a condenser, having an outlet connected to the inlet of the heat sink and an inlet connected to the outlet of the heat sink; and
a magnetocaloric pump, for providing a magnetic field to the ferrofluid flowing in the heat sink.

2. The microchannel cooling device of claim 1, wherein the depth of each microchannel is 200 μm.

3. The microchannel cooling device of claim 1, wherein the width of each microchannel is ranged between 80 μm and 100 μm.

4. The microchannel cooling device of claim 1, wherein the magnetocaloric pump further comprises:
a first permanent magnet, being disposed at the inlet of the heat sink; and
a second permanent magnet, being disposed at the outlet of the heat sink;
wherein the direction of the magnetic field is in the direction pointed from the inlet of the heat sink to the outlet of the heat sink.

5. The microchannel cooling device of claim 1, wherein the magnetocaloric pump further comprises a concave for accommodating the heat sink while the magnetic polarity of the portion of the concave next to the inlet of the heat sink is North and the magnetic polarity of the portion of the concave next to the outlet of the heat sink is South.

6. The microchannel cooling device of claim 1, wherein the ferrofluid further comprises a fluoride liquid and a plurality of magnetic particles.

7. The microchannel cooling device of claim 6, wherein the magnetic particle is a nano-scale iron particle.

8. The microchannel cooling device of claim 7, wherein the nano-scale iron particle is a particle selected from the group consisting of Fe₂O₃, Fe₃O₄ and the mixtures thereof.

9. The microchannel cooling device of claim 6, the fluoride liquid is FC-72.

10. The microchannel cooling device of claim 1, further comprising: a two-phase conduit for connecting the outlet of the heat sink to the inlet of the condenser; and a conduit with pure liquid flowing therein for connecting the outlet of the condenser to the inlet of the heat sink.

11. The microchannel cooling device of claim 1, wherein the heat sink further comprises a microchannel system formed by superimposing a cover on a substrate having a plurality of micro-grooves arranged thereon.
